(19) United States
(12) Patent Application Publication
(10) Pub. No.: US 2007/0138616 A1
(43) Pub. Date: Jun. 21, 2007

(54) Semiconductor device and manufacturing method of the same

(75) Inventors: Tetsuya Fujisawa, Kawasaki (JP); Kaname Ozawa, Kawasaki (JP); Mitsutaka Sato, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/703,702

(22) Filed: Feb. 8, 2007

Related U.S. Application Data
(63) Continuation of application No. PCT/JP04/13629, filed on Sep. 17, 2004.

(51) Int. Cl. H01L 23/48

(52) U.S. Cl. 257/690

(57) ABSTRACT

A semiconductor device, includes a supporting board; and a semiconductor element mounted on a first main surface of the supporting board. The supporting board includes a first electrode formed on the first main surface, a second electrode formed on a second main surface, and an opening or notch forming part. A first electrode pad of the semiconductor element faces and is connected to the first electrode of the supporting board. A second electrode pad of the semiconductor element and the second electrode of the supporting board are electrically connected via the opening or notch forming part.

### CROSS-REFERENCE TO RELATED APPLICATION

This application is a U.S. continuation application filed under 35 USC 111(a) claiming benefit under 35 USC 120 and 365(c) of PCT application JP04/013629, filed Sep. 17, 2004. The foregoing application is hereby incorporated herein by reference.

### BACKGROUND OF THE INVENTION

1. Field of the Invention

The present invention generally relates to semiconductor devices and manufacturing methods of the same. More particularly, the present invention relates to a semiconductor device where plural semiconductor elements are mounted on a single supporting board in a coplanar manner and a manufacturing method of the semiconductor device.

2. Description of the Related Art

A BGA (ball grid array) type or LGA (land grid array) type semiconductor device, for example, has a structure where a semiconductor element is mounted on a supporting board. An example of such a BGA type semiconductor device is shown in FIG. 1 as a semiconductor device 1A.

As shown in FIG. 1, the BGA type semiconductor device 1A has a structure where a semiconductor element 2A is provided on a main surface of a supporting board 3A. Outside connection electrodes 6 are provided on a rear surface of the supporting board 3A. Bonding pads 4 formed on the main surface of the supporting board 3A and the semiconductor element 2A are connected to each other by wires 5.

FIG. 2 is a plan view showing the arrangement of wirings 7 of the related art semiconductor device 1A shown in FIG. 1. As shown in FIG. 2, wirings 7 whose end parts are connected to the bonding pads 4 are formed on the main surface of the supporting board 3A. The other end parts of the wirings 7 are connected to the outside connection electrodes 6 provided on the rear surface of the supporting board 3A via through hole forming parts 15. Solder balls forming outside connection terminals are provided on the outside connection electrodes 6.

In the related art semiconductor device like the semiconductor device 1A shown in FIG. 1, it is general practice that a single semiconductor element 2A is mounted or provided on a single supporting board 3A. Because of this, an arrangement position of the semiconductor element 2A is the center position of the supporting board 3A where it is possible to easily arrange the wirings 7.

However, recently miniaturization or high functionality of electronic device such as a portable type information device has been required. Therefore, a semiconductor device is required to have both a small size and high functionality or large capacity. Because of this, a semiconductor device where plural semiconductor elements are mounted on a single supporting board, such as an MCM (multi-chip module) type or SiP (system in package) type semiconductor device, has been suggested. See, for example, Japanese Laid-Open Patent Application Publication No. 2000-196008.

FIG. 3 is a plan view of such a SiP type semiconductor device 1B. In the semiconductor device 1B shown in FIG. 3, a semiconductor element 2B is mounted and provided on a supporting board in parallel with the semiconductor element 2A. Here, the semiconductor element 2A is, for example, a logic chip such as a microprocessor, and the semiconductor element 2B is, for example, a memory chip such as a flash memory. Generally, the number of outside connection terminal pads of the semiconductor element 2A required to have high functions is larger than the number of outside connection terminal pads of the normal semiconductor element 2B.

The semiconductor elements 2A and 2B are connected to the bonding pads 4 formed on the supporting board 3B by the wires 5. Since plural semiconductor elements, namely the semiconductor elements 2A and 2B, are mounted on a single supporting board 3B in a coplanar manner, the position of the semiconductor element 2A on the supporting board 3B is offset from the center position of the supporting board 3B.

FIG. 4 is a plan view showing arrangement of wirings 7 formed on the supporting board 3B in the case where the mounting position of the semiconductor element 2A is offset from the center position of the supporting board 3B. As shown in FIG. 4, since two semiconductor elements 2A and 2B are provided on the supporting board 3B, the arrangement of the wiring 7 formed on the supporting board 3B is close. Within an area indicated by an arrow X, namely where the semiconductor element 2A and an edge part of the supporting board 3B are close, the area where the wirings 7 can be arranged is small. Hereinafter, an area where wirings can be arranged is called a wirings arrangement area. This is discussed with reference to FIG. 5 through FIG. 7.

FIG. 5 is a plan view showing the arrangement of pads of the semiconductor element 2A shown in FIG. 1 or FIG. 3. As shown in FIG. 5, the semiconductor elements 2A has a rectangular-shaped configuration. Plural outside connection bonding pads 10 are provided in the vicinities of outer peripheries of four sides, namely an outer periphery first side 11A through an outer periphery fourth side 11D, of the rectangular-shaped configuration of the semiconductor elements 2A. More specifically, the outside connection bonding pads 10 are provided in parallel with the outer periphery first side 11A through the outer periphery fourth side 11D.

FIG. 6 is a plan view showing wirings arrangement areas of the semiconductor device 1A where such a semiconductor element 2A is mounted and provided in the center of the supporting board 3A. As shown in FIG. 6, four wirings arrangement areas are formed on the supporting board 3A corresponding to four sides of the outer periphery of the semiconductor element 2A.

In other words, a first wirings arrangement area 12A corresponding to the outer periphery first side 11A, a second wirings arrangement area 12B corresponding to the outer periphery first side 11B, a third wirings arrangement area 12C corresponding to the outer periphery first side 11C, and a fourth wirings arrangement area 12D corresponding to the outer periphery first side 11D are formed. Hereinafter, the first through fourth wirings arrangement areas 12A through 12D are called first through fourth areas 12A through 12D.

In the case of the semiconductor device 1A shown in FIG. 6 where the semiconductor element 2A is arranged in the center of the supporting board 3A, the first through fourth areas 12A through 12D have substantially equal areas. Therefore, arrangement of the wirings on the supporting board 3A can be made substantially equally in the first through fourth areas 12A through 12D so that the wirings 7 can be arranged securely.

FIG. 7 is a plan view showing wirings arrangement areas of the semiconductor device 1B shown in FIG. 3. In this case, since the position of the semiconductor element 2A is offset from the center of the supporting board 3B, the first through fourth areas 13A through 13D are not the same. As shown in FIG. 7, in a case where the semiconductor element 2A is offset to the right side, the third area 13C is largest and the first area 13A is smallest.

Accordingly, in a case where the same number of the wirings 7 arranged in the third area 13C are arranged in the narrowest first area 13A, it is difficult to design and form the arrangement of the wirings 7.

In addition, in order to avoid this problem, the first area 13A may be made larger. However, this may cause an increase of the area of the supporting board 3B so that it may not be possible to respond to the requirement of miniaturization of the semiconductor device 1B.

In order to solve such a problem, as shown in FIG. 8 and FIG. 9, a supporting board 3C may have a multilayer structure including interlayer connection via forming parts 20 and wiring layers 21, and the semiconductor element 2A may be flip-chip mounted on the supporting board 3C in a face-down state. Here, FIG. 8 and FIG. 9 are first and second views for explaining the reason why bumps are not connected on via forming parts formed in the supporting board 3C. Under this structure, outside connection pads are provided right under the semiconductor element and therefore it is possible to prevent or restrain an increase in the area of the supporting board 3C.

However, in the examples shown in FIG. 8 and FIG. 9, it is difficult to make a pitch P1 of via forming parts 20 formed in the supporting board 3C correspond to a pitch P2 of the pads 10 formed on the semiconductor element 2A. In addition, the multilayer structure may cause an increase of cost of the supporting board.

### SUMMARY OF THE INVENTION

Accordingly, embodiments of the present invention may provide a novel and useful semiconductor device and manufacturing method of the same in which one or more of the problems described above are eliminated.

More specifically, the embodiments of the present invention can provide a semiconductor device where arrangement of wirings can be easily made regardless of mounting or arrangement positions of semiconductor elements on a supporting board so that the semiconductor device can be miniaturized, and a manufacturing method of the semiconductor device.

The embodiments of the present invention can also provide a semiconductor device, including a supporting board; and a semiconductor element mounted on a first main surface of the supporting board; wherein the supporting board includes a first electrode formed on the first main surface, a second electrode formed on a second main surface, and an opening or notch forming part; a first electrode pad of the semiconductor element faces and is connected to the first electrode of the supporting board; and a second electrode pad of the semiconductor element and the second electrode of the supporting board are electrically connected via the opening or notch forming part.

In the semiconductor device, the opening or notch forming part may be provided in the vicinity of an edge part of a side or the vicinity of a corner part of the supporting board. The opening or notch forming part may be provided in the vicinity of edge parts of a plurality of sides or the vicinity of a plurality of corner parts of the supporting board. The second electrode pad of the semiconductor element may be connected to the second electrode of the second main surface of the supporting board by a wire passing through the opening or the notch forming part so that the second electrode pad of the semiconductor element and the second electrode of the supporting board are electrically connected to each other. The semiconductor element and the wire may be sealed by resin. The resin sealing the wire may have a projection part, the projection part projecting on the second main surface of the supporting board, and the height of the projection part from the supporting board may be less than the height of an outside terminal projecting from the second main surface of the supporting board. The height of the projection part from the supporting board may be equal to or less than 1/2 of the height of the outside terminal projecting from the second main surface of the supporting board. A wiring layer contacting the second electrode may be formed on the second main surface of the supporting board, and an outside terminal is formed on the wiring layer. A plurality of the semiconductor elements may be mounted over the supporting board. A plurality of the semiconductor elements may be stacked over the supporting board. A dam configured to block leakage of the resin may be provided in the vicinity of an end part or the opening of the second main surface of the supporting board.

The embodiments of the present invention can also provide a manufacturing method of a semiconductor device, including the steps of: forming a supporting board having a first electrode formed on a first main surface of the supporting board, a second electrode formed on a second main surface of the supporting board, and an opening or notch forming part; mounting a semiconductor element on the first main surface of the supporting board so that a second electrode pad of the semiconductor element faces the opening or notch forming part; connecting a first electrode pad of the semiconductor element to the first electrode; and electrically connecting the second electrode pad of the semiconductor element to the second electrode of the supporting board via the opening or notch forming part.

In the manufacturing method of the semiconductor device, the opening or notch forming part may be formed in the vicinity of an edge part of a side of the supporting board or the vicinity of a corner part, in the step of forming the supporting board. The manufacturing method of the semiconductor device may further include the step of sealing the semiconductor element and the opening or notch forming part with resin after the step of connecting the second electrode pad to the second electrode.

According to the embodiments of the present invention, a rear surface of the supporting board is used as an arrangement area of wirings directly connected to an electrode pad of the semiconductor element mounted on the supporting board. Therefore, it is possible to form a miniaturized semiconductor device at low cost without making the supporting board have a multilayer structure.

Other objects, features, and advantages of the present invention will become more apparent from the following detailed description when read in conjunction with the accompanying drawings.

### BRIEF DESCRIPTION OF THE DRAWINGS

FIG. 1 is a plan view of a related art semiconductor device where a single semiconductor element is provided;

FIG. 2 is a plan view showing the arrangement of wirings of the related art semiconductor device shown in FIG. 1;

FIG. 3 is a plan view of a related art semiconductor device where two semiconductor elements are provided;

FIG. 4 is a plan view showing the arrangement of wirings of the related art semiconductor device shown in FIG. 3;

FIG. 5 is a plan view showing the arrangement of pads of a semiconductor element 2A shown in FIG. 1 or FIG. 3;

FIG. 6 is a plan view showing wirings arrangement areas of the related art semiconductor device shown in FIG. 1;

FIG. 7 is a plan view showing wirings arrangement areas of the related art semiconductor device shown in FIG. 3;

FIG. 8 is a first view for explaining the reason why bumps are not connected on via forming parts formed in a supporting board;

FIG. 9 is a second view for explaining the reason why bumps are not connected on via forming parts formed in the supporting board;

FIG. 10 is a plan view of a semiconductor device of a first embodiment of the present invention;

FIG. 11 is a cross-sectional view of the semiconductor device of the first embodiment of the present invention taken along line X1-X1 in FIG. 10;

FIG. 12 is a plan view showing the arrangement of pads of a semiconductor element 32 shown in FIG. 10;

FIG. 13 is a plan view showing wirings arrangement area in the first embodiment of the present invention;

FIG. 14 is a plan view showing the arrangement of wiring on a surface of a substrate used in the semiconductor device of the first embodiment of the present invention;

FIG. 15 is a plan view showing the arrangement of wiring on the rear surface of the substrate used in the semiconductor device of the first embodiment of the present invention;

FIG. 16 is an enlarged cross-sectional view of the vicinity of a slit forming part of the semiconductor device of the first embodiment of the present invention;

FIG. 17 is an enlarged bottom view of the vicinity of the slit forming part of the semiconductor device of the first embodiment of the present invention;

FIG. 18 is a cross-sectional view of a semiconductor device of a second embodiment of the present invention;

FIG. 19 is a cross-sectional view of a semiconductor device of a third embodiment of the present invention;

FIG. 20 is a cross-sectional view of a semiconductor device of a fourth embodiment of the present invention;

FIG. 21 is an enlarged cross-sectional view of the vicinity of a slit forming part of a semiconductor device of a fifth embodiment of the present invention;

FIG. 22 is an enlarged and cross-sectional view of the vicinity of a slit forming part of a semiconductor device of a sixth embodiment of the present invention;

FIG. 23 is a cross-sectional view of a semiconductor device of a seventh embodiment of the present invention;

FIG. 24 is a cross-sectional view of a semiconductor device of an eighth embodiment of the present invention;

FIG. 25 is a cross-sectional view of a semiconductor device of a ninth embodiment of the present invention;

FIG. 26 is an enlarged bottom view of the vicinity of a slit forming part of a semiconductor device of a tenth embodiment of the present invention;

FIG. 27 is a cross-sectional view of the semiconductor device of the tenth embodiment of the present invention taken along line X2-X2 in FIG. 26;

FIG. 28 is an enlarged cross-sectional view of a part indicated by an arrow B in FIG. 27;

FIG. 29 is a first view for explaining a forming position of a slit forming part;

FIG. 30 is a second view for explaining the forming position of the slit forming part;

FIG. 31 is a third view for explaining the forming position of the slit forming part;

FIG. 32 is a first view for explaining a forming position of a notch part;

FIG. 33 is a second view for explaining the forming position of the notch part;

FIG. 34 is a third view for explaining the forming position of the notch part;

FIG. 35 is a fourth view for explaining the forming position of the notch part;

FIG. 36 is a fifth view for explaining the forming position of the notch part;

FIG. 37 is a sixth view for explaining the forming position of the notch part;

FIG. 38 is a flowchart showing a manufacturing method of the semiconductor device of the embodiment of the present invention;

FIG. 39A is a plan view for explaining a preparation process of a board sheet with a slit forming part;

FIG. 39B is a bottom view for explaining the preparation process of the board sheet with the slit forming part;

FIG. 40A is a plan view for explaining a flip chip bonding process;

FIG. 40B is a cross-sectional view for explaining a flip chip bonding process;

FIG. 41A is a plan view for explaining a wire bonding process;

FIG. 41B is a cross-sectional view for explaining a wire bonding process;

FIG. 42A is a plan view for explaining a resin sealing process;

FIG. 42B is a cross-sectional view for explaining the resin sealing process;

FIG. 43 is a plan view for explaining a dicing process; and

FIG. 44 is a plan view for explaining a solder ball providing process.

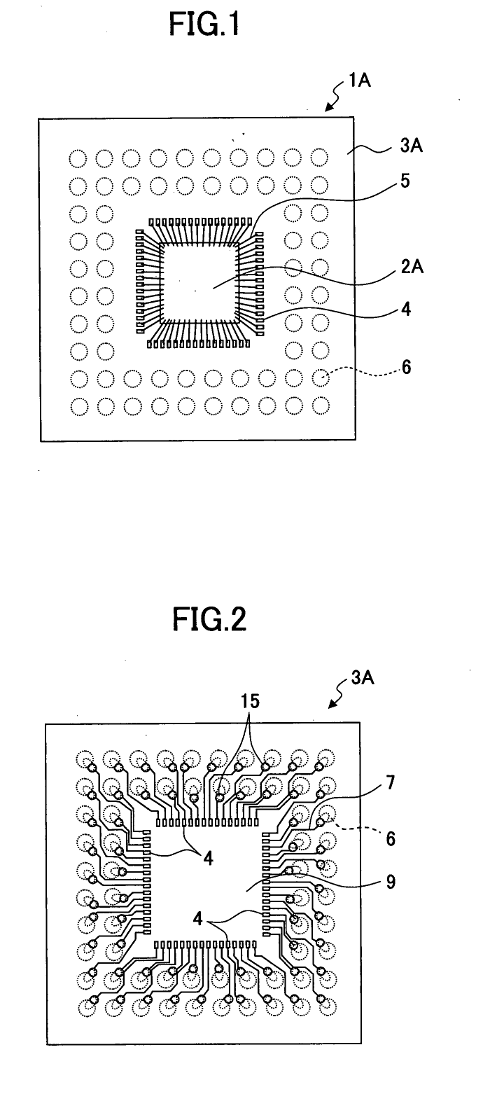

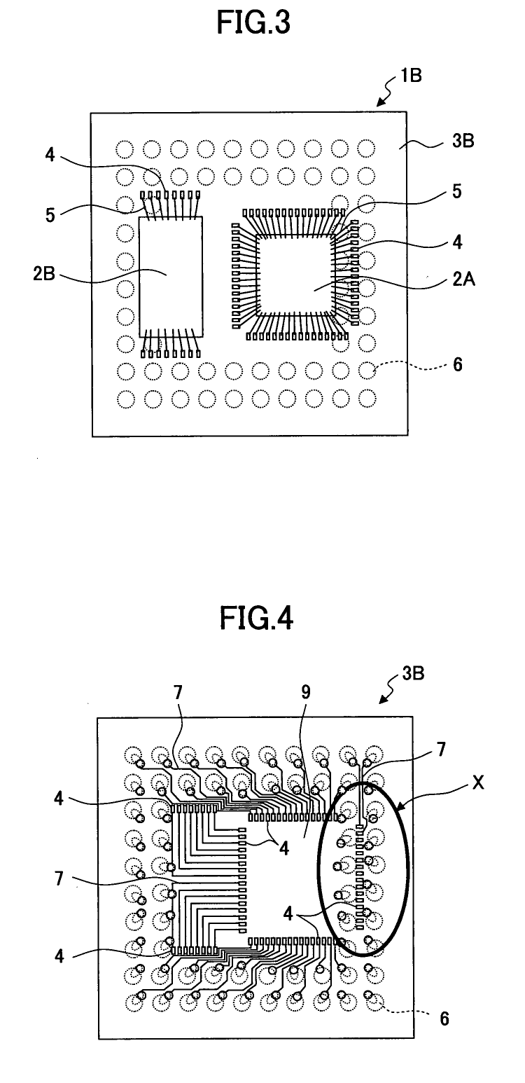

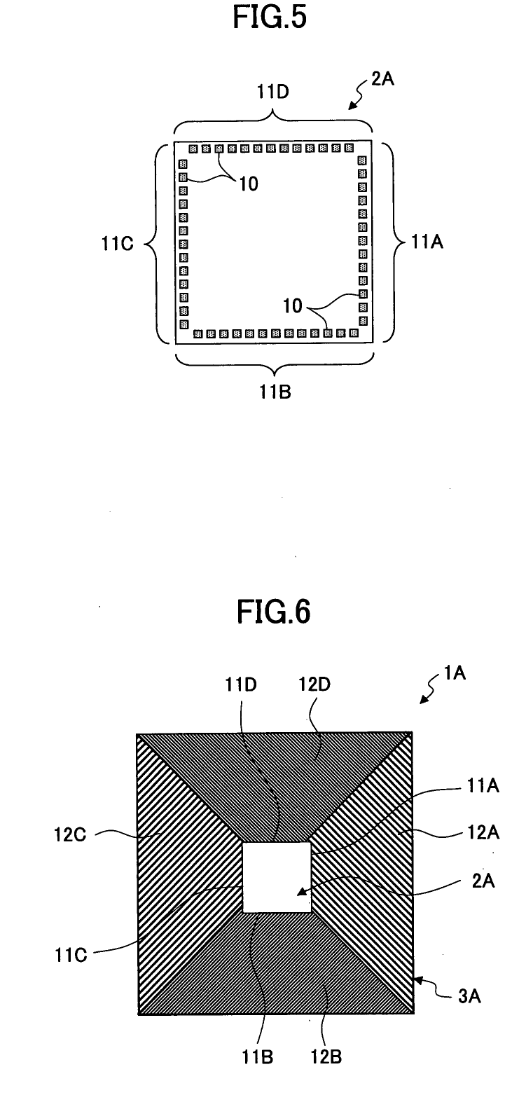

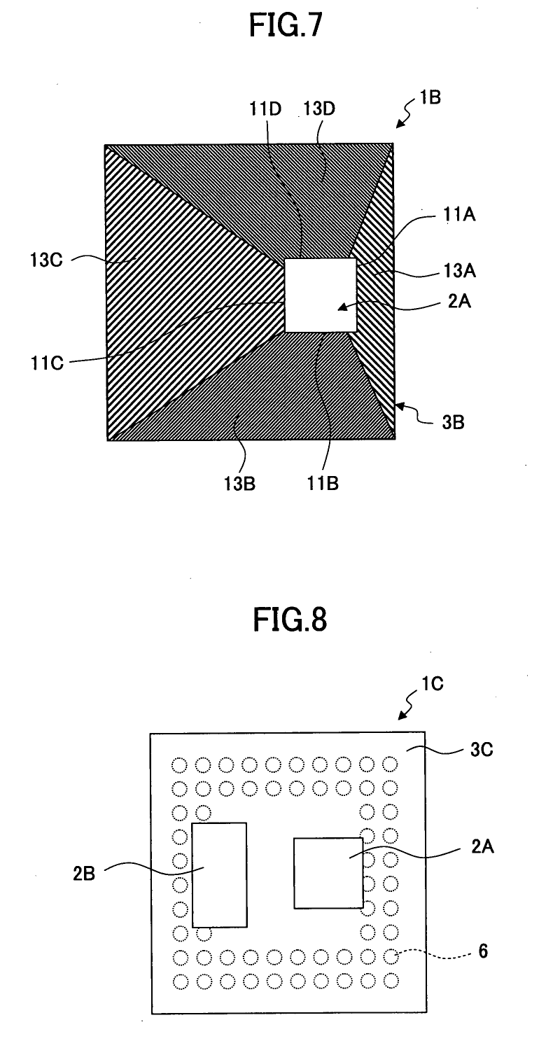

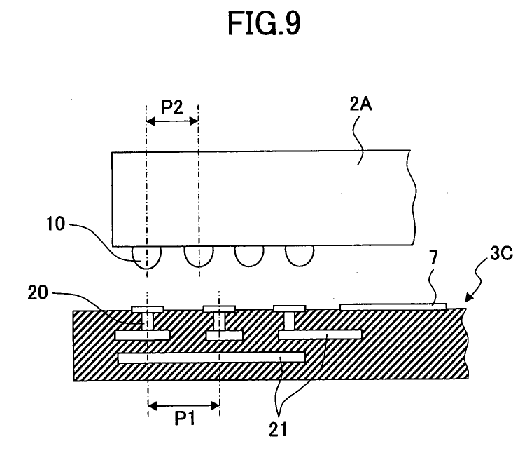

### DETAILED DESCRIPTION OF THE PREFERRED EMBODIMENT

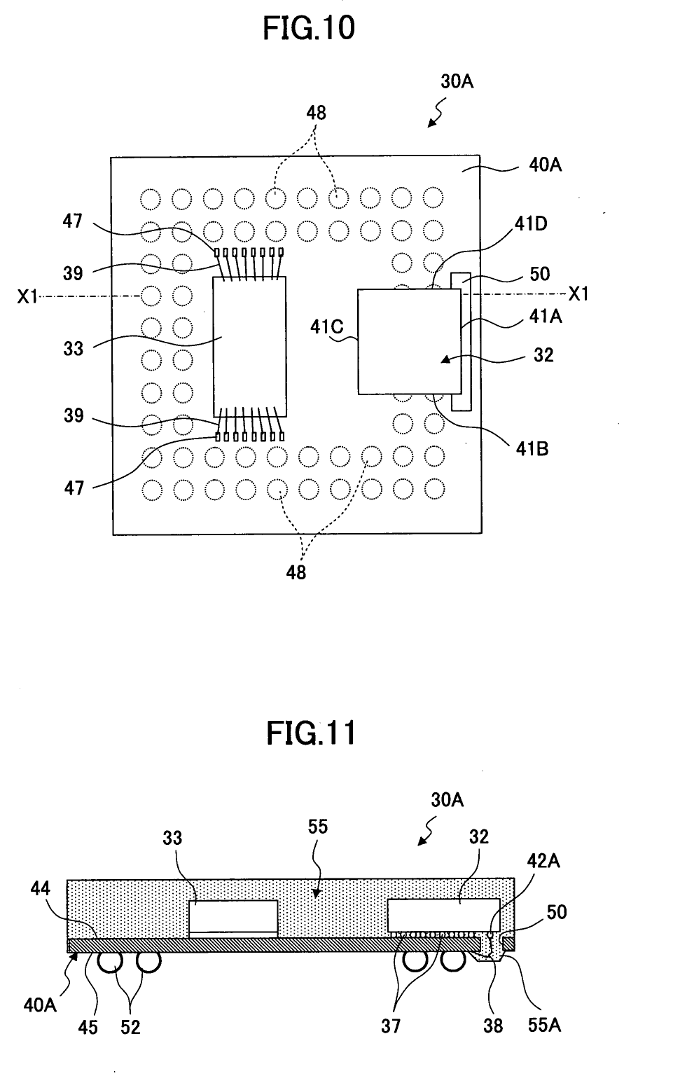

A description will now be given, with reference to FIG. 10 through FIG. 44, of embodiments of the present invention.

### First Embodiment of the Present Invention

A semiconductor device 30A of a first embodiment of the present invention is discussed with reference to FIG. 10 through FIG. 17. As shown in FIG. 10 and FIG. 11, the semiconductor device 30A includes a first semiconductor element 32, a second semiconductor element 33, a supporting board 40A, a sealing resin part 55, outside connection terminals 52, and others.

The first semiconductor element 32 is, for example, a logic chip such as a microprocessor, and the second semiconductor element 33 is, for example, a memory chip such as a flash memory. As shown in FIG. 10 and FIG. 11, in this embodiment, a part of electrodes of the semiconductor element 32 mounted on an upper surface of the supporting board 40A is connected to a lower surface of the supporting board 40A via a slit forming part (opening part) 50 provided in the supporting board 40A by wires 38 so as to be electrically connected to a wiring pattern (not shown in FIG. 10 and FIG. 11) of the lower surface of the supporting board 40A.

In other words, the first semiconductor element 32 is mounted in the vicinity of the edge part of the supporting board 40 and is situated in a position offset from the center part of the supporting board 40A, so that arranging the wirings into a wiring pattern on the upper surface of the supporting board 40A may be difficult. However, at least a part of the electrode pad of the semiconductor element 32 is connected to the lower surface of the supporting board 40A via the slit forming part (opening part) 50 by the wire 38. Thus, the rear surface of the supporting board 40A is used as a wiring area.

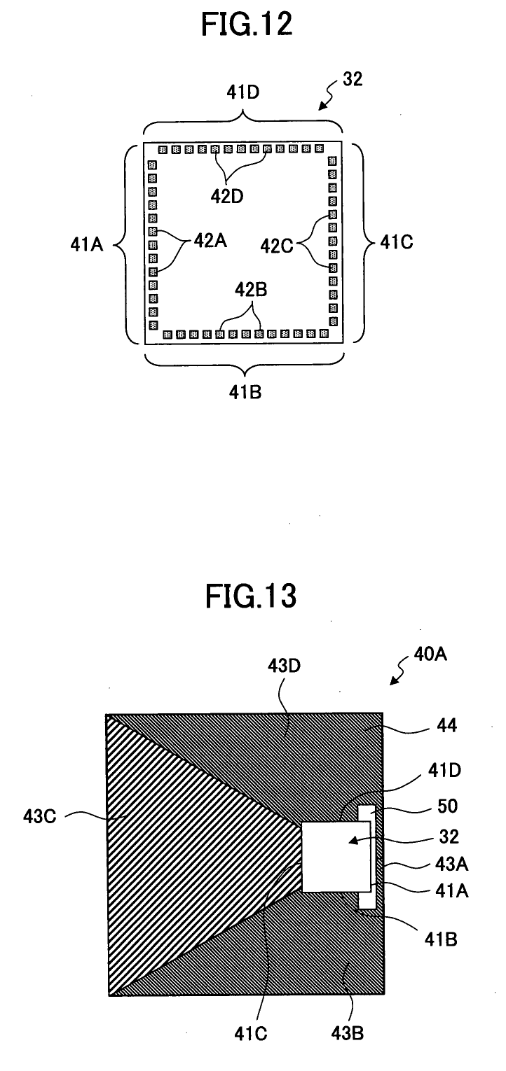

In order to realize this structure, in the semiconductor device 30A of this embodiment, flip-chip bonding projection electrodes 37 and wire bonding pads are selectively provided at the outside connection electrode pad parts provided in the vicinities of four sides of the semiconductor element 32 shown in FIG. 12.

That is, in this embodiment, pads (a pad line) 42A situated along the side 41A corresponding to the first area 43A that is narrowest among the wiring areas of the supporting board 40A where the semiconductor element 32 is mounted are used as the wire bonding pads. On the other hand, projection electrodes 37 (not shown in FIG. 12) made of solder balls are provided on pads (pad lines) 42B through 42D. Here, the pads (pad lines) 42B through 42D are provided along the sides 41B through 41D corresponding to the second through fourth areas 43B through 443D larger than the first area 43A among the wiring areas of the supporting board 40A.

In other words, the first semiconductor element 32 has an outside connection electrode structure where the first semiconductor element 32 is mounted and arranged on the supporting board 40A by a flip-chip bonding method. A lead can be connected to the selected pad by a wire bonding method.

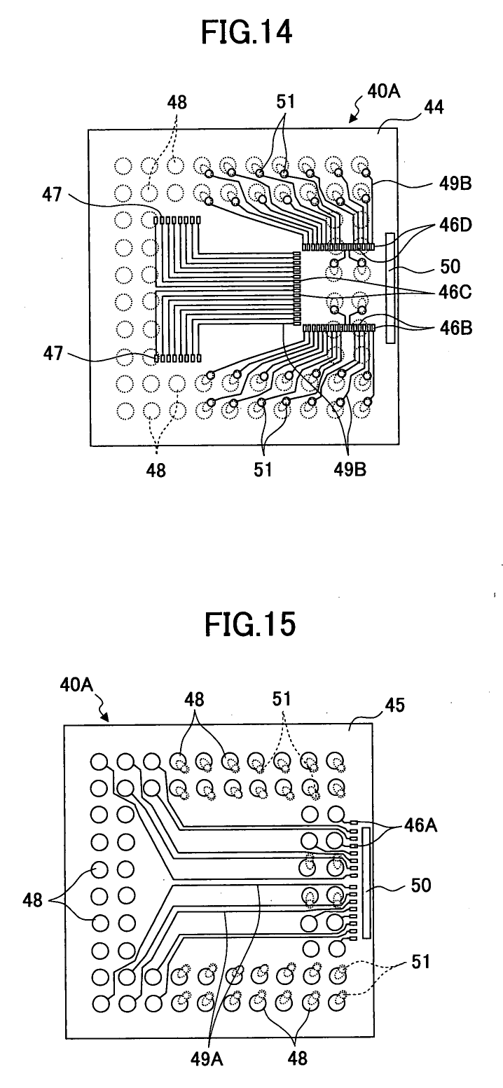

A wiring pattern and arrangement structure of pads on a front surface 44 and a rear surface 45 of the supporting board 40A where such a semiconductor element 32 is mounted are shown in FIG. 14 and FIG. 15. An insulation material such as glass epoxy is used as a basic material of the plate-shaped supporting board 40. The wiring pattern and the electrode pads are selectively provided on the front and rear surfaces of the supporting board 40. Such a supporting board 40A is called an interposer.

The wiring patterns and/or the electrode pads provided on the front and rear surfaces of the supporting board 40A are electrically or mechanically connected to each other through a mutual connection part VIA piercing the plate-shaped board 40A if necessary.

As shown in FIG. 14, front surface side bonding pads 46B through 46D, bonding pads 47, front surface side wirings 49B and others are provided on the front surface 44 of the supporting board 40A. On the other hand, as shown in FIG. 15, rear surface side bonding pads 46A, outside connection electrodes 48, rear surface side wirings 49A and others are provided on the rear surface 45 of the supporting board 40A.

A slit forming part 50 piercing the supporting board 40A is provided at a part corresponding to the first area 43A of the supporting board 40A. In other words, when the first semiconductor element 32 is provided and mounted on a designated position on the supporting board 40A, the slit forming part 50 is provided in a position corresponding to the pads 42A of the first semiconductor element 32.

The slit forming part 50 has a configuration and measurements so that the wires 38 can be connected between the pads 42A of the first semiconductor element 32 and the rear surface side bonding pads 46A of the supporting board 40A via the slit forming part 50.

The pads 42B through 42D of the flip chip bonded first semiconductor element 32 are connected to the bonding pads 46B through 46D situated on the front surface 44 of the supporting board 40A via the projection electrodes 37. On the other hand, the wires 39 connecting to the bonding pads of the second semiconductor element 33 are connected to the bonding pads 47. Since the second semiconductor element 33 is a memory chip and arrangement of the outside connection pads of the second semiconductor element 33 is normally normal, the number of pads of the second semiconductor element 33 is smaller than that of the first semiconductor element 32. Accordingly, the second semiconductor element 33 is connected to the bonding pads 47 formed on the supporting board 40A by the wires 39. The second semiconductor element 33 may be connected to the supporting board 40A by a flip-chip bonding method.

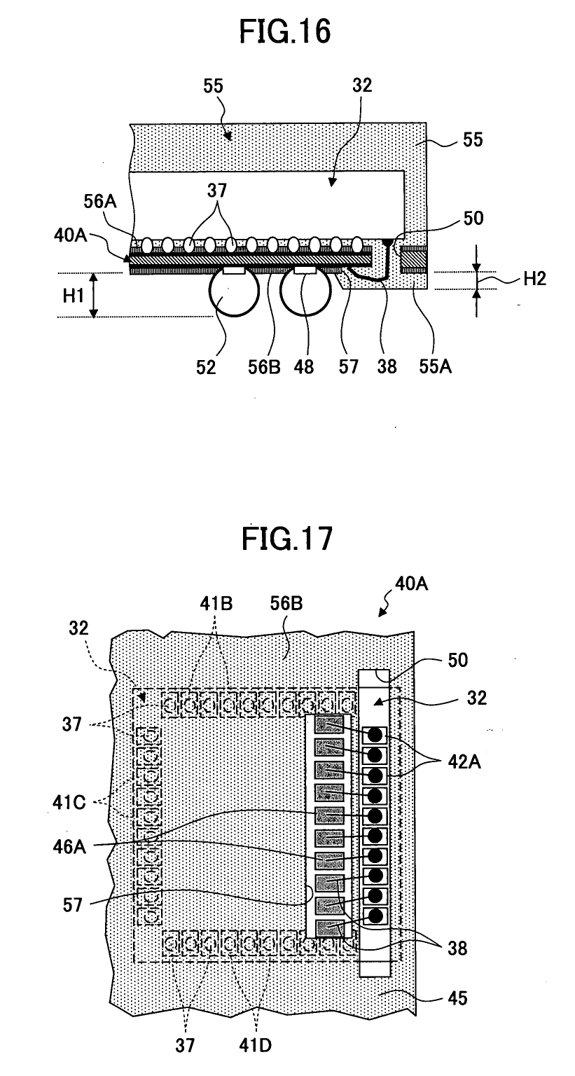

Ends of the surface side wirings 49B, whose other ends are connected to the bonding pads 46B and 46D, are connected via through hole forming parts 51 piercing the supporting board 40A. In addition, ends of the surface side wirings 49B, whose other ends are connected to the front surface side bonding pads 46C, are connected to the bonding pads 47. As shown in FIG. 16, a solder resist layer 56A is formed on the front surface 44 so as to protect the wirings 49B shown in FIG. 14.

On the other hand, as shown in FIG. 16 and FIG. 17, ends of the wires 38 led out via the slit forming part 50 are connected to the electrode pads 42A of the first semiconductor element 32. The other ends of the wires 38 are connected to the bonding pads 46A situated on the rear surface 45 of the supporting board 40A. In addition, the outside connection terminals 52 made of solder balls are provided, as shown in FIG. 11 and FIG. 16, on the outside connection electrodes 48.

A part of the outside connection electrodes 48 is electrically connected to the bonding pads 46B and 46D via the through hole forming parts 51 piercing the supporting board 40A. In addition, the outside connection electrodes 48 not connected via the through hole forming parts 51 are not connected are connected to the rear surface side bonding pads 46A. As shown in FIG. 16 and FIG. 17, a solder resist layer 56B is formed on the rear surface 45 so as to protect the wirings 49A shown in FIG. 15. An opening part 57 is provided in a position facing the bonding pads 46A in the solder resist 56B so as to expose the bonding pads 46A. Furthermore, as shown in FIG. 17, the pads 42A of the first semiconductor element 32 can be seen via the slit forming part 50 from the rear surface 45 side of the supporting board 40A.

In the semiconductor device 30A having the above-discussed structure, the first semiconductor element 32 is provided and mounted on the supporting board 40A where the slit forming part 50 is selectively provided. The selected electrode pads 42A of the first semiconductor element 32 are connected to the rear surface side bonding pads 46A formed on the rear surface of the supporting board 40A via the slit forming part 50 by wire bonding. While the rear surface side bonding pads 46A are connected to the outside connection electrodes 48 by the surface side wiring 49A, the surface side wiring 49A can be formed on the rear surface 45 of the supporting board 40A except forming positions of the outside connection electrodes 48. Therefore, the degree of freedom of arrangement of the rear surface side wiring 49A is high.

In other words, the rear surface 45 of the supporting board 40A is used as an arrangement area of the wirings so that the degree of freedom of arrangement on the front surface 44 is improved. Hence, it is possible to make the semiconductor device 30A miniaturized and have high densities so that accelerating of the semiconductor device 30A can be achieved.

According to this embodiment, since the first semiconductor element 32 is connected to the supporting board 40A by flip chip bonding, it is possible to make the mounting area smaller than a mounting structure by a wire bonding method. Hence, it is possible to save space required for electrically connecting between the first semiconductor element 32 and the supporting board 40A.

The first semiconductor element 32 and the second semiconductor element 33 provided and mounted on the supporting board 40A discussed above are sealed by a sealing resin part 55 as shown in FIG. 16. The sealing resin part 66 can be formed by, for example, a transfer molding process using epoxy resin.

The sealing resin enters the rear surface 45 of the supporting board 40A via the slit forming part 50 so as to seal the wires 38. The wires 38 are protected by the sealing resin. As shown in FIG. 16, a height H2 of the sealing resin part covering the wires 38, namely a projection part 55A from the rear surface 45 (supporting board 40A) is less than a height H1 of the outside connection terminals 52 from the rear surface 45.

Under this structure, it is possible to prevent the projection part 55A from being an obstacle for mounting the semiconductor device 30A on a mounting board (not shown) installed in an electronic device by using the outside connection terminals 52. It is preferable that the height H2 of the projection part 55A be equal to or less than ½ of the height H1 of the outside connection terminal 52, namely H2 ≦H½.

### Second Embodiment of the Present Invention

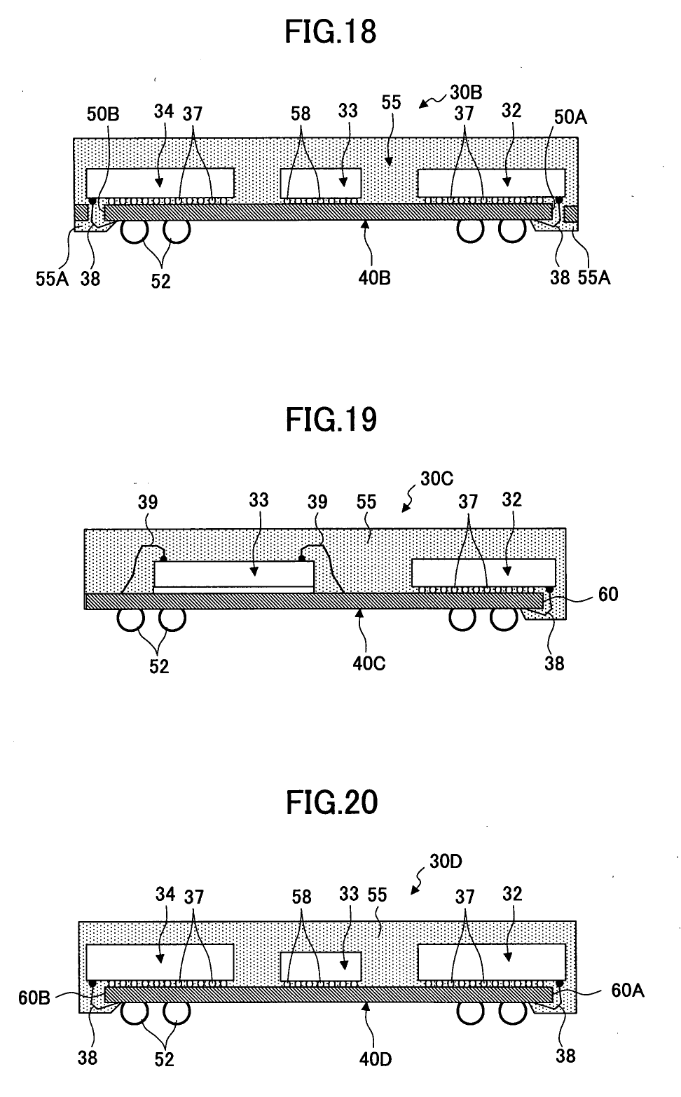

Next, a second embodiment of the present invention is discussed. FIG. 18 is a cross-sectional view of a semiconductor device 30B of the second embodiment of the present invention. In FIG. 18,.parts that are the same as the parts of the above-discussed semiconductor device 30A of the first embodiment of the present invention are given the same reference numerals, and explanation thereof is omitted.

In the second embodiment of the present invention, three semiconductor elements 32 through 34 are provided and mounted on a single supporting board 40B. Under this structure, the first semiconductor element 32 and the third semiconductor element 34 are logic chips having a large number of outside connection pads. The second semiconductor element 33 is a memory chip having a relatively small number of the outside connection pads.

As shown in FIG. 18, the first semiconductor element 32 is situated in a position offset from the center to the right side. The third semiconductor element 34 is situated in a position offset from the center to the left side. The second semiconductor element 33 is provided between the first and third semiconductor elements 32 and 34. In this embodiment, the second semiconductor element 33 is connected to the supporting board 40B by flip chip bonding.

Slit forming parts 50A and 50B are formed at left and right parts, respectively, of the supporting board 40A. A wire 38 connects the first semiconductor element 32 to the rear surface of the supporting board 40B via the slit forming part 50A. A wire 38 connects the third semiconductor element 34 to the rear surface of the supporting board 40B via the slit forming part 50B.

Thus, in the case where two semiconductor elements 32 and 34 each having a large number of pads are mounted on a single supporting board, the degree of freedom of arrangement of wirings on the front surface of the supporting board 40A is lower than that of the first embodiment of the present invention. However, in the second embodiment of the present invention, pads corresponding to narrow wirings arrangement areas at end parts of the supporting board 40B among the pads 42A through 42D of the semiconductor elements 32 and 34 are connected to the rear surface of the supporting board 40B by the wires 38 via the slit forming parts 50A and 50B provided in the supporting board 40B.

Under this structure, even if plural semiconductor elements or a semiconductor element having a large number of outside connection pads is provided and mounted on a single supporting board, it is possible to achieve miniaturization or high density of the semiconductor device.

### Third Embodiment of the Present Invention

Next, a third embodiment of the present invention is discussed. FIG. 19 is a cross-sectional view of a semiconductor device 30C of the third embodiment of the present invention.

In the semiconductor device 30C of the third embodiment of the present invention, as shown in FIG. 19, a notch forming part 60 is formed at an edge part of the supporting board 40C and a wire 38 connects the semiconductor element 32 to the rear surface of the supporting board 40C via the notch forming part 60. In other words, in this embodiment, the notch forming part 60 instead of the slit forming part 50 of the first embodiment is used.

Under this structure, the semiconductor element 32 is provided so that an edge part of the semiconductor element 32 is situated in the vicinity of an outer periphery edge part of the supporting board 40C or outside the vicinity of an outer periphery edge part of the supporting board 40C. Hence, it is possible to miniaturize the semiconductor device 30C.

### Fourth Embodiment of the Present Invention

Next, a fourth embodiment of the present invention is discussed. FIG. 20 is a cross-sectional view of a semiconductor device 30D of the fourth embodiment of the present invention.

In the semiconductor device 30D of the fourth embodiment of the present invention, as shown in FIG. 20, notch forming parts 60A and 60B instead of the slit forming parts 50A and 50B in the semiconductor device 30B of the second embodiment are provided at corresponding end parts of a supporting board 40D. In the semiconductor device 30D as compared to the semiconductor device 30B, it is possible to achieve miniaturization.

### Fifth and Sixth Embodiments of the Present Invention

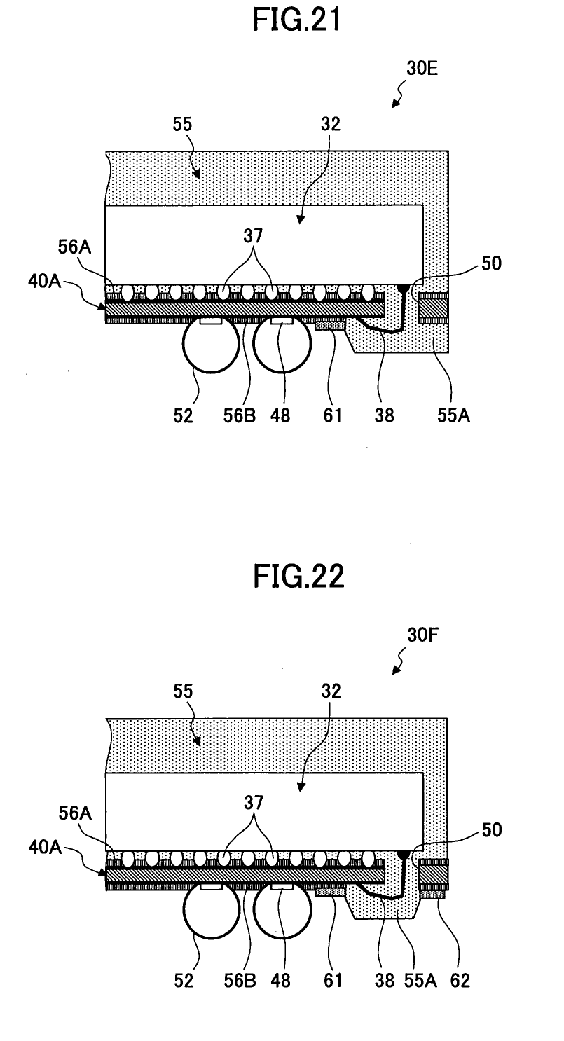

Next, fifth and sixth embodiments of the present invention are discussed. FIG. 21 is a cross-sectional view of a semiconductor device 30E of the fifth embodiment of the present invention and FIG. 22 is a cross-sectional view of a semiconductor device 30F of the sixth embodiment of the present invention.

In the semiconductor device 30E of the fifth embodiment, a dam 61 configured to block flow of the sealing resin is provided in the vicinity of the slit forming part 50. In the semiconductor device 30F of the sixth embodiment, dams 61 and 62 configured to block flow of the sealing resin are provided in the vicinity of the slit forming part 50.

The dams 61 and 62 are made of the same material as the solder resist 56B and therefore are formed in a lump when the solder resist 56B is formed. Therefore, the manufacturing process does not become complex due to forming the dams 61 and 62.

In the semiconductor device 30E of the fifth embodiment, the dam 61 is provided between the slit forming part 50 and the outside connection terminal 52 on the supporting board 40A. Under this structure, even if the sealing resin enters the rear surface side of the supporting board 40A via the slit forming part 50 when the sealing resin 55 is formed, the flow of the sealing resin is blocked by the dam 61. Accordingly, it is possible to prevent the sealing resin from reaching the forming position of the outside connection terminals 52, namely the outside connection electrodes 48, and therefore the outside connection terminals 52 can be securely formed on the outside connection electrodes 48.

On the other hand, in the semiconductor device 30F shown in FIG. 22 of the fifth embodiment, the dam 62 in addition to the dam 61 is formed in an outside position of the slit forming part 50. Under this structure, it is possible to prevent the sealing resin from flowing and being adhered to the outer periphery side of the supporting board 40A.

### Seventh through Ninth Embodiments of the Present Invention

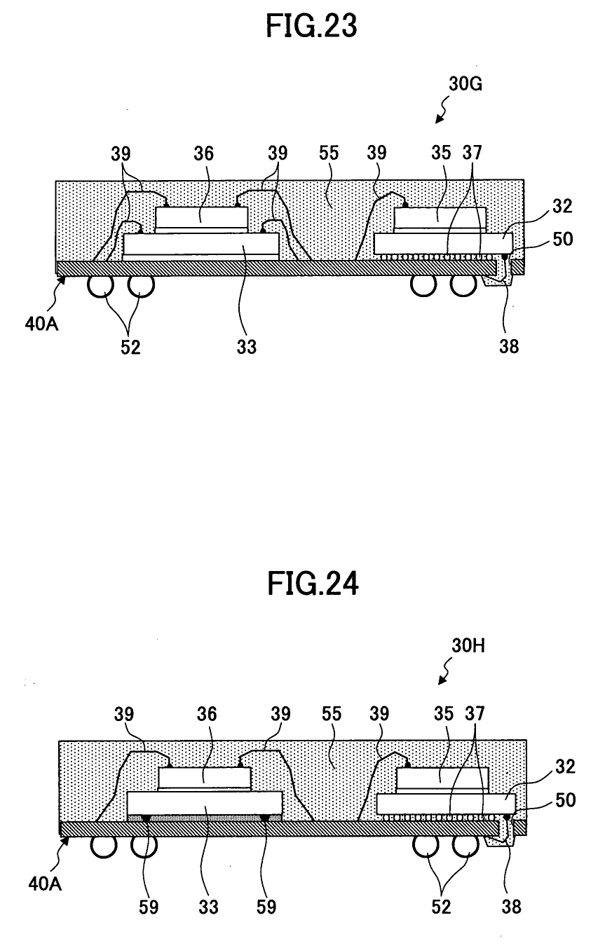

Next, seventh through ninth embodiments of the present invention are discussed. FIG. 23 through FIG. 25 are cross-sectional views of semiconductor devices 30G through 30I, respectively, of the seventh through ninth embodiments of the present invention. In the semiconductor devices 30G through 30I of the seventh through ninth embodiments of the present invention, plural semiconductor elements are stacked.

In the semiconductor device 30G shown in FIG. 23 of the seventh embodiment of the present invention, a semiconductor element 35 is mounted on the first semiconductor element 32 and a semiconductor element 36 is mounted on the second semiconductor element 33 under the structure of the semiconductor device 30A shown in FIG. 10 of the first embodiment of the present invention. The semiconductor elements 35 and 36 are electrically connected to the pads of the supporting board 40A by using wires 39.

In the semiconductor device 30H shown in FIG. 24 of the eighth embodiment of the present invention, the second semiconductor element 33 has bumps 59 and is connected to the supporting board 40A by flip-chip bonding under the structure of the semiconductor device 30G shown in FIG. 23.

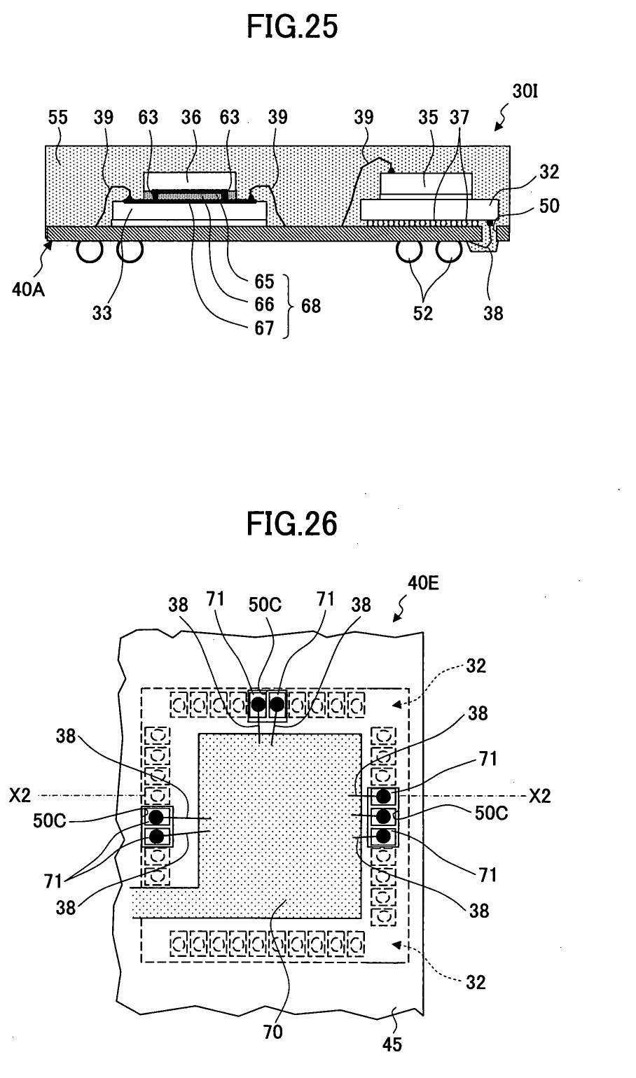

In the semiconductor device 30I shown in FIG. 25 of the ninth embodiment of the present invention, the second semiconductor element 33 is connected to the supporting board 40A by using the wires 39 and a semiconductor element 36 is provided on the second semiconductor element 33 by flip-chip bonding. A decoupling condenser 68 is formed between the second semiconductor element 33 and the semiconductor element 36.

The decoupling condenser 68 is formed by a ground metal layer 65, a dielectric layer 66, and an electric power metal layer 67. The ground metal layer 65 is formed on a rear surface of the semiconductor element 36. The electric power metal layer 67 is formed on an upper surface of the second semiconductor element 33. The dielectric layer 66 is provided between the ground metal layer 65 and the electric power metal layer 67. Thus, since the decoupling condenser 68 is provided between the second semiconductor element 33 and the semiconductor element 36, it is possible to improve an electric characteristic when a high frequency signal is used.

In the semiconductor devices 30G through 30I, while high functionality can be achieved by making the semiconductor elements 32 through 36 form stacking structures, the number of wiring is increased. However, in these embodiments, a part of the pads of the semiconductor elements is connected to the rear surface of the supporting board 40A via the slit forming part 50 by the wires 38 and the rear surface of the supporting board 40A is applied as the wiring area. Therefore, in these embodiments, it is possible to respond to the increase of the wirings. The slit forming part 50 may be changed to the notch part if necessary.

### Tenth Embodiment of the Present Invention

Next, a tenth embodiment of the present invention is discussed with reference to FIG. 26 through FIG. 28. FIG. 26 is the enlarged bottom view of the vicinity of a slit forming part of a semiconductor device 30J of the tenth embodiment of the present invention.

In the above-discussed semiconductor devices 30A through 30I, the slit forming part 50 is provided in the vicinity of the edge part of the supporting board in the narrow wiring arrangement area formed on the supporting board or the notch forming part 60 is provided at the edge part of the supporting board in the narrow wiring arrangement area formed on the supporting board or the notch forming part 60. Via such a slit forming part 50 or the notch forming part 50, the pads of the corresponding semiconductor element are connected to the rear surface of the supporting board by the wires 38. Under this structure, it is possible to make the semiconductor devices 30A through 30I miniaturized and have high densities.

On the other hand, in a semiconductor device 30J of the tenth embodiment of the present invention, selected ones among plural outside connection pads of the semiconductor element 32, which is flip-chip mounted on a supporting board 40E, regardless of positions of the pads, are connected to the rear surface 45 of the supporting board 40E via the slit forming part 50C provided in the supporting board 40E by the wires 38. An electric power conductive layer (or ground conductive layer) 70 is selectively provided on the rear surface 45 of the supporting board 40E and the wires 38 are connected to the electric power conductive layer (or ground conductive layer) 70.

In other words, as shown in FIG. 26, in this embodiment, a slit forming part 50C is formed in a position corresponding to the forming position of an electric power pad 71 of the first semiconductor element 32. The electric power pads 71 are connected to the electric power conductive layer 70 formed on the rear surface 45 of the supporting board 40E by the wires 38. The relatively large-area electric power conductive layer 70 is provided on a part of the rear surface of the supporting board 40E corresponding to a position where the first semiconductor element 32 is provided and mounted.

Under this structure, as shown in FIG. 28, signal wirings 69 formed on the front surface 44 of the supporting board 40E and the electric power conductive layer 70 formed on the rear surface 45 of the supporting board 40E form a micro strip line. Because of this, even if high frequency signals are sent in the signal wirings 69, noise is not generated and therefore it is possible to maintain good electric characteristic of the semiconductor device 30J.

In this embodiment, the electric power conductive layer is used as a conductive layer formed on the rear surface of the supporting board 40E. However, the present invention is not limited to this. A ground conductive layer may be provided on the rear surface of the supporting board 40E. In this case, a ground pad of the first semiconductor element 32 is connected to the ground conductive layer via the wire 38.

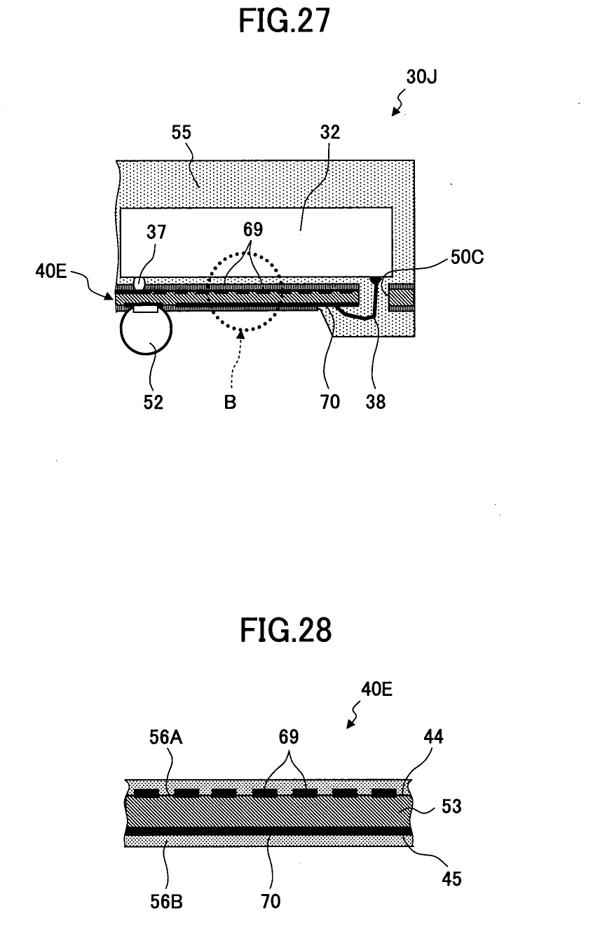

FIG. 27 is a cross-sectional view of the semiconductor device of the tenth embodiment of the present invention taken along line X2-X2 in FIG. 26. More specifically, FIG. 27 shows a part of the supporting board 40E where the electric power conductive layer 70 is provide in an enlarged manner. FIG. 28 is an enlarged cross-sectional view of a part indicated by an arrow B in FIG. 27.

As shown in FIG. 27 and FIG. 28, in the supporting board 40E, the signal wirings 69 are formed on a front surface 44 of a board core 53 and the electric power conductive layer 70 is formed on a rear surface 45 of the board core 53. The signal wirings 69 are covered with a solder resist 56A and the electric power conductive layer 70 is covered with a solder resist 56B.

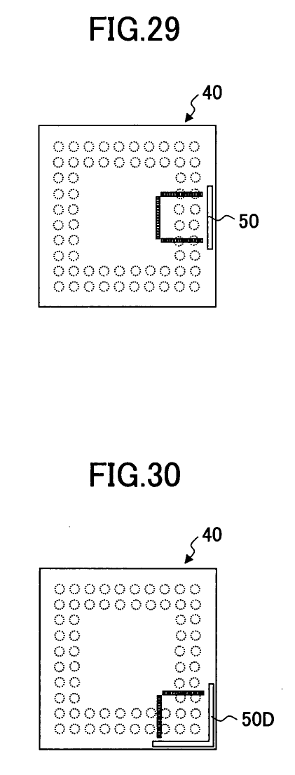

FIG. 29 through FIG. 37 show modified examples of a forming position and a configuration of the slit forming part 50 or the notch forming part 60 in the supporting board 40. In FIG. 29 through FIG. 37, positions of the pads 42 of the semiconductor element as correspond to the position or configuration of the slit forming part 50 or the notch forming part 60.

In the example shown in FIG. 29, a straight shape slit forming part is formed at an edge part of a side of the supporting board 40.

In the example shown FIG. 30, an L-shaped slit forming part 50D is formed at a corner part of the supporting board 40. In this structure, two sides among outer periphery four sides 41A through 41D of the semiconductor element 32 face the slit forming part 50D. Thus, the slit forming part or the notch forming part is formed corresponding to not only a single side among the outer periphery four sides 41A through 41D of the semiconductor element 32 but also plural necessary sides.

A side of the semiconductor element 32 where the slit forming part or the notch forming part is formed is selected as follows. That is, a single side or two sides are selected from three sides corresponding to the wirings arrangement areas 43A through 43D around the semiconductor element 32 other than the largest wiring arrangement area at the supporting board where the semiconductor element 32 is mounted. In this case, the side of the semiconductor element 32 corresponding to the narrowest wirings arrangement area has a priority to be selected. Next, the side of the semiconductor element 32 corresponding to the second narrowest wirings arrangement area is selected.

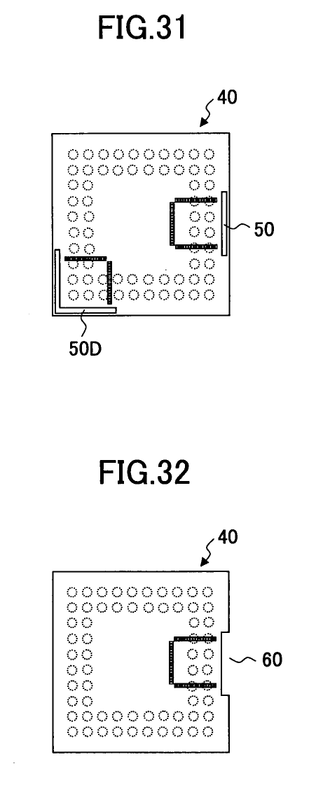

The example shown in FIG. 31 is a combination of the example shown in FIG. 29 and the example shown in FIG. 30.

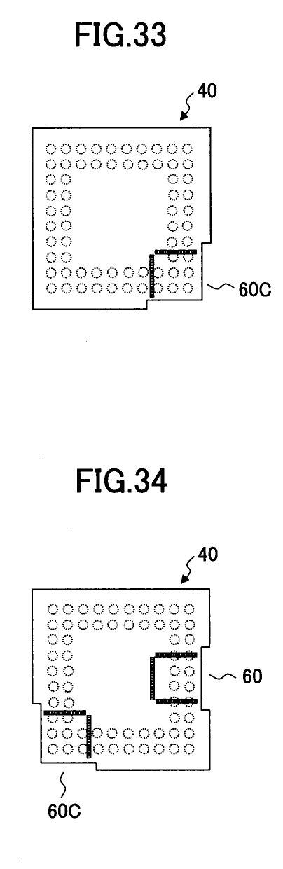

In the examples shown in FIG. 32 through FIG. 34, the notch forming part 60 instead of the slit forming part 50 is formed. More specifically, in the example shown in FIG. 32, the notch forming part 60 having a rectangular shape without one side is formed at an edge part of the selected one side of the supporting board 40. In the example shown in FIG. 33, an L-shaped notch forming part 60C is formed at a corner part of the supporting board 40. The example shown in FIG. 34 is a combination of the example shown in FIG. 32 and the example shown in FIG. 33.

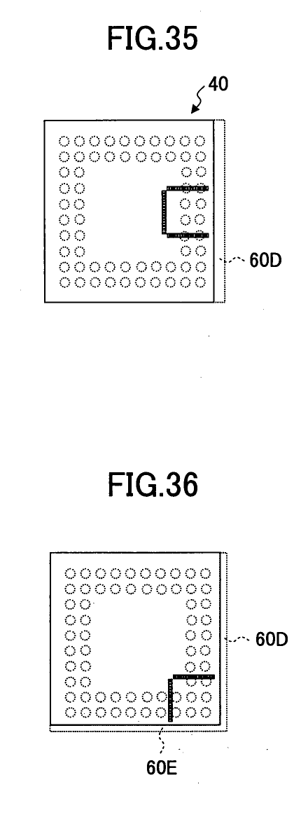

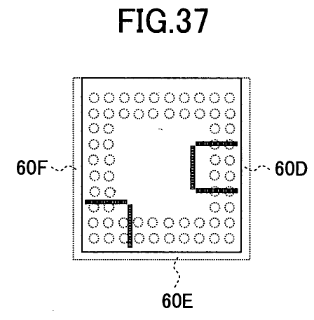

In the examples shown in FIG. 35 through FIG. 37, a notch forming part 60D, 60E, and 60F are selectively formed at entireties of side edges of the supporting board 40. More specifically, in the example shown in FIG. 35, the notch forming part 60D is formed at an entirety of a right side edge of the supporting board 40. In the example shown in FIG. 36, in addition to the notch forming part 60D shown in FIG. 35, a notch forming part 60E is formed at the entirety of the lower side edge of the supporting board 40. In the example shown in FIG. 37, in addition to the notch forming parts 60D and 60E shown in FIG. 36, a notch forming part 60F is formed at the entirety of the left side edge of the supporting board 40.

Forming positions of the slit forming part and the notch forming part are not limited to the structures shown in FIG. 29 through FIG. 37. Forming positions proper for miniaturization or high densities can be selected, if necessary, as the forming positions of the slit forming part and the notch forming part, depending on the number of pads of the semiconductor element, the position of the semiconductor element on the supporting board, the position of the outside connection electrode, and others.

Next, an example of a manufacturing method of the semiconductor device of the embodiment of the present invention is discussed. In the following explanation, an example of a manufacturing method of the semiconductor device 30K shown in FIG. 44 is discussed. In the semiconductor device 30K shown in FIG. 44, the first semiconductor element 32 and the second semiconductor element 33 are provided on the supporting board 40C.

Under this structure, pads formed in a position corresponding to a relatively wide wirings arrangement area of the supporting board 40C among the pads of the first semiconductor element 32 are flip-chip bonded to the supporting board 40C by bumps 37.

On the other hand, pads formed in a position corresponding to a narrow wirings arrangement area of the supporting board 40C are connected (wire bonded) to the rear surface side bonding pads 46A on the rear surface of the supporting board 40C via the notch forming part 60 by the wires 38. In addition, the second semiconductor element 33 is flip-chip bonded to the supporting board 40C. In addition, the first and second semiconductor elements 32 and 33 are sealed by the sealing resin part 55.

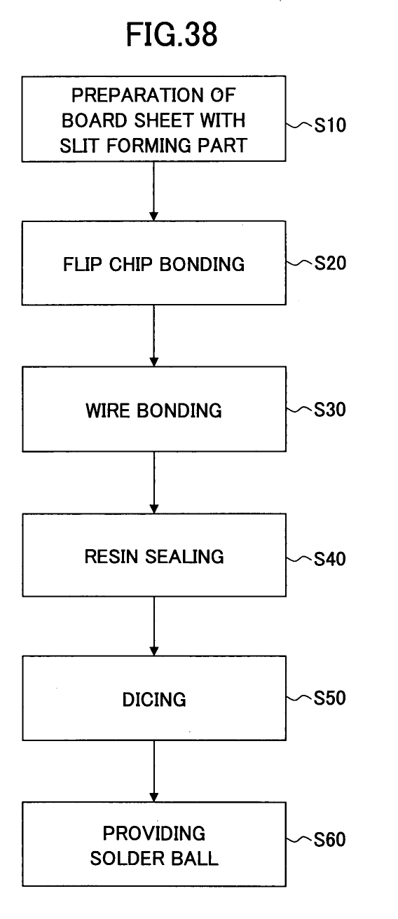

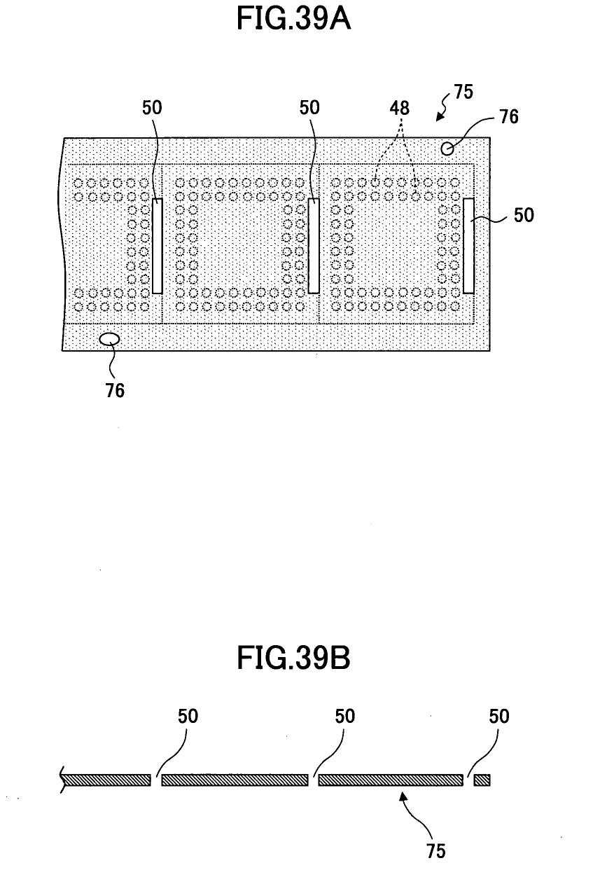

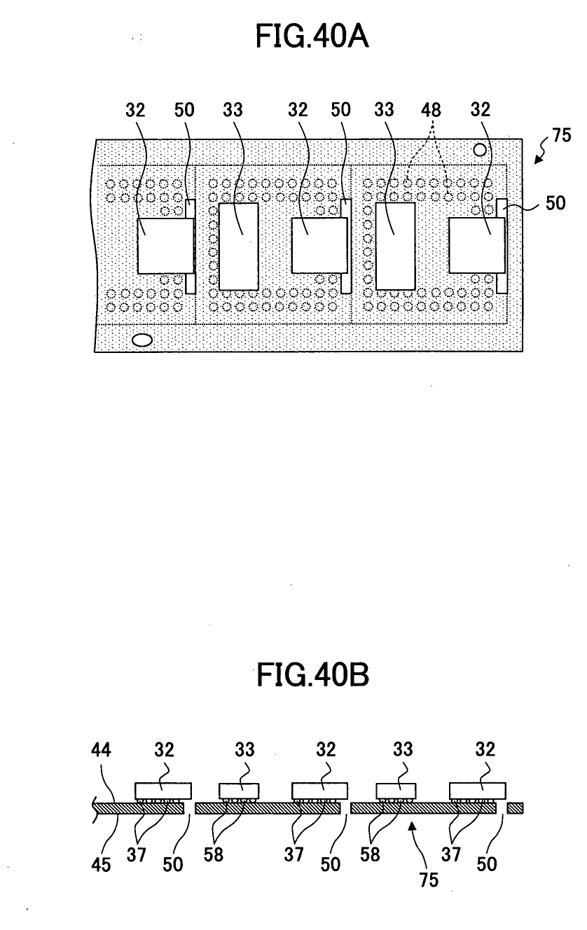

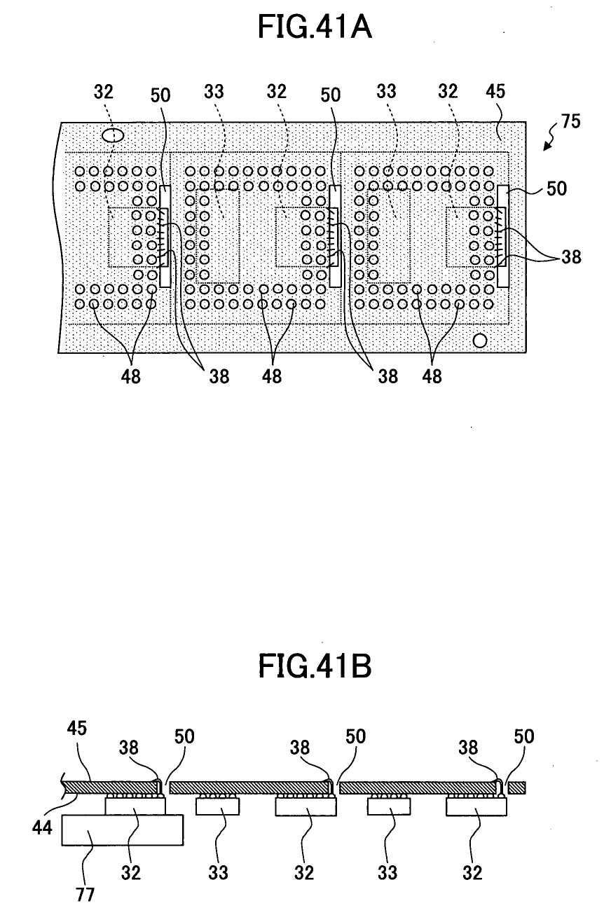

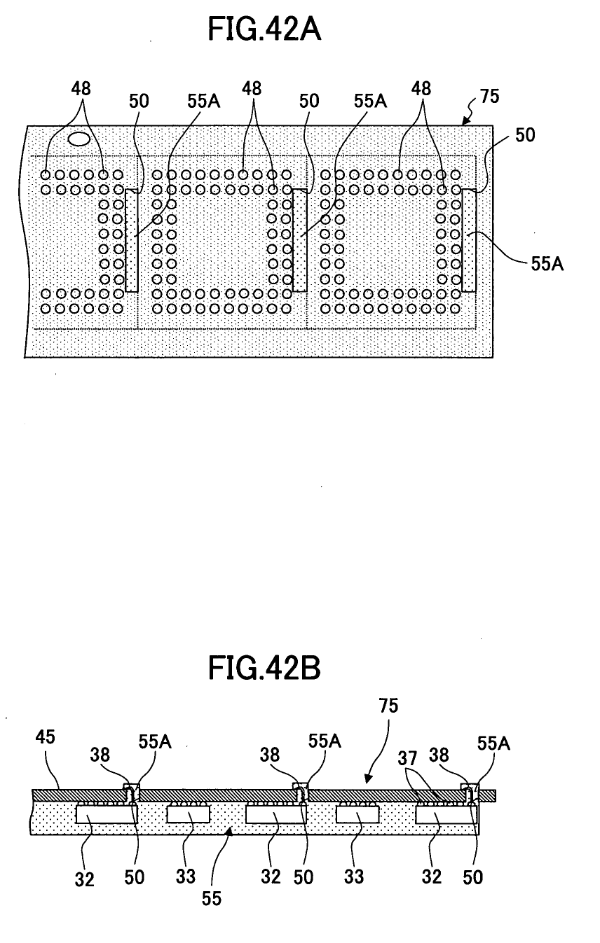

The semiconductor device 30K having the above-mentioned structure is manufactured by processes of step 10 through step 60 shown in FIG. 38. A process of each of the steps is discussed with reference to FIG. 39 through FIG. 44. FIG. 39A and FIG. 40A are plan views and FIG. 39B and FIG. 40B are side cross-sectional views. FIG. 41A and FIG. 42A are bottom views and the FIG. 41B and FIG. 42B are side cross-sectional views.

First, as shown in FIG. 39A and FIG. 39B, a supporting board sheet 75 having the slit forming parts 50 is formed in step 10. In this example, in order to simultaneously form plural semiconductor devices 30K from a single supporting board sheet 75, plural forming areas of the semiconductor devices 30K, three areas in the example shown in FIG. 39A and FIG. 39B, are formed in the supporting board sheet 75.

The supporting board sheet 75 is formed by a multilayer wiring technique so as to have the outside connection electrodes 48, the surface side bonding pads, the rear surface side bonding pads, surface side wirings, rear surface side wiring, bonding pads, and through hole forming parts. The slit forming part 50 is also formed in the supporting board sheet 75 in advance by a press process. At this time, positioning-hole forming parts 76 for positioning the supporting board sheet 75 are also formed.

Next, the first semiconductor elements 32 and the second semiconductor elements 33 are flip-chip bonded on the supporting board sheet 75 in step 20. FIG. 40A and FIG. 40B show a state where the first semiconductor elements 32 and the second semiconductor elements 33 are flip-chip bonded on the supporting board sheet 75.

Here, the pads formed in positions facing the relatively wide wirings arrangement area of the first semiconductor element 32 are flip-chip bonded to pads on the supporting board sheet 75 via the bumps 37. On the other hand, the pads formed in positions facing the narrow wirings arrangement area of the first semiconductor element 32 face the slit forming part 50 formed in the supporting board sheet 75.

In step 30, a wire bonding process is implemented so that the semiconductor element 32 and the rear surface of the supporting board sheet 75 are connected by the wires 38. FIG. 41A and FIG. 41B show the wire bonding process.

In the process in step 20, designated pads of the semiconductor element 32 are positioned in the slit forming part 50. Via the slit forming part 50, the wire 38 connect the pads of the semiconductor element 32 and the rear surface side bonding pads (not shown in FIG. 41A and FIG. 41B) formed on the rear surface 45 of the supporting board 75. At this time, as shown in FIG. 41B, the wire bonding process is performed where the semiconductor element 32 is supported by a heat block 77.

In step 40, a resin sealing process is implemented. Epoxy resin is supplied by using a transfer molding method in the resin sealing process, so that the sealing resin part 55 is formed. When the sealing resin part 55 is formed, a part of the sealing resin enters the rear surface 45 of the supporting board sheet 75 via the slit forming part 50 so as to seal the wires 38 and form the projection part 55A.

FIG. 42A and FIG. 42B show a state where the sealing resin part 55 is formed. In this case, by providing the dam on the supporting board sheet 75, it is possible to prevent unnecessary flow of the sealing resin.

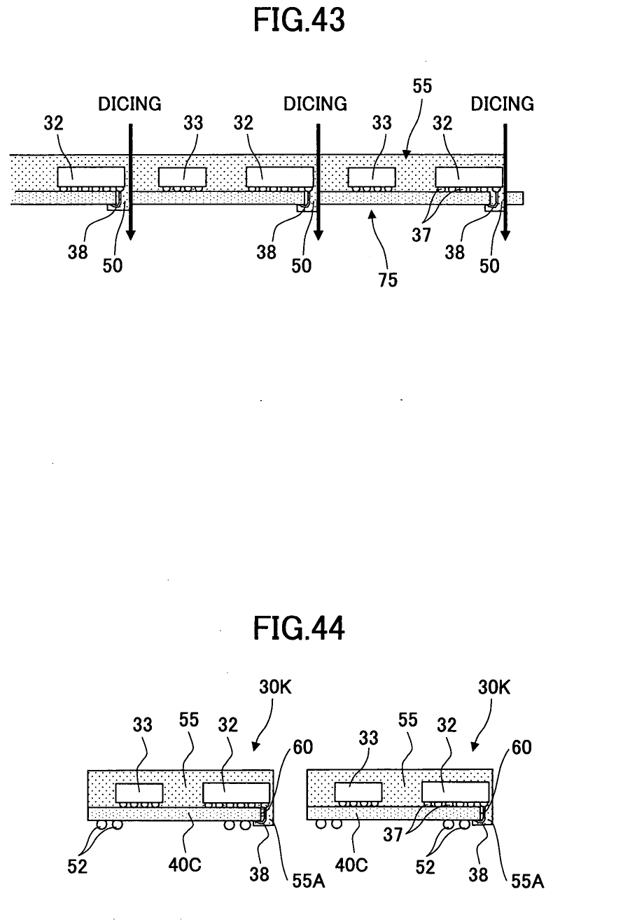

In step 50, as shown in FIG. 43, the supporting board sheet 75 and the sealing resin part 55 are continuously cut by using a dicing blade (not shown in FIG. 43) so that pieces of the supporting board sheet 75 and the sealing resin part 55 are made. In this example, the dicing blade cuts along inside of the slit forming parts 50. Accordingly, the notch forming parts 60 are formed at edge parts where the slit forming parts 50 are provided among edge parts of the supporting board 40C being cut from the supporting board sheet 75.

After the dicing process is completed, in step 60 solder balls as the outside connection terminals 52 are provided on the pads on the rear surface of the supporting board 40C and thereby the semiconductor device 30K shown in FIG. 44 is formed.

According to the manufacturing method of this example, a part of plural pads formed on the semiconductor element 32, namely the pads facing the narrow wiring arrangement area, are positioned so as to face the slit forming part 50 formed in the supporting board sheet 75. In addition, the pads of the semiconductor element are connected to the rear surface side bonding pads formed on the rear surface 45 of the supporting board sheet 75 via the slit forming part 50 by wire bonding.

Because of this, even if the semiconductor element 32 is provided on the front surface 44 of the supporting board sheet 75, the pads formed on the semiconductor element 32 can be easily and securely wire-connected to the rear surface side bonding pads formed on the rear surface 45 of the supporting board sheet 75.

In the above-discussed example, the solder ball is used as the outside connection terminal having a projection configuration. However, the present invention is not limited to this example. For example, a gold (Au) bump can be applied, if necessary, as the outside connection terminal.

The present invention is not limited to these embodiments, but variations and modifications may be made without departing from the scope of the present invention.

What is claimed is:

1. A semiconductor device, comprising:
a supporting board; and
a semiconductor element mounted on a first main surface of the supporting board;
wherein the supporting board includes a first electrode formed on the first main surface, a second electrode formed on a second main surface, and an opening or notch forming part;
a first electrode pad of the semiconductor element faces and is connected to the first electrode of the supporting board; and
a second electrode pad of the semiconductor element and the second electrode of the supporting board are electrically connected via the opening or notch forming part.

2. The semiconductor device as claimed in claim 1,
wherein the opening or notch forming part is provided in the vicinity of an edge part of a side or the vicinity of a corner part of the supporting board.

3. The semiconductor device as claimed in claim 2,
wherein the opening or notch forming part is provided in the vicinity of edge parts of a plurality of sides or the vicinity of a plurality of corner parts of the supporting board.

4. The semiconductor device as claimed in claim 1,
wherein the second electrode pad of the semiconductor element is connected to the second electrode of the second main surface of the supporting board by a wire passing through the opening or the notch forming part so that the second electrode pad of the semiconductor element and the second electrode of the supporting board are electrically connected to each other.

5. The semiconductor device as claimed in claim 4,
wherein the semiconductor element and the wire are sealed by resin.

6. The semiconductor device as claimed in claim 5,
wherein the resin sealing the wire has a projection part, the projection part projecting on the second main surface of the supporting board; and
the height of the projection part from the supporting board is less than the height of an outside terminal projecting from the second main surface of the supporting board.

7. The semiconductor device as claimed in claim 6,
wherein the height of the projection part from the supporting board is equal to or less than ½ of the height of the outside terminal projecting from the second main surface of the supporting board.

8. The semiconductor device as claimed in claim 1,
wherein a wiring layer contacting the second electrode is formed on the second main surface of the supporting board; and
an outside terminal is formed on the wiring layer.

9. The semiconductor device as claimed in claim 1,
wherein a plurality of the semiconductor elements are mounted over the supporting board.

10. The semiconductor device as claimed in claim 1,
wherein a plurality of the semiconductor elements are stacked over the supporting board.

11. The semiconductor device as claimed in claim 5,
wherein a dam configured to block leakage of the resin is provided in the vicinity of an end part or the opening of the second main surface of the supporting board.

12. A manufacturing method of a semiconductor device, comprising the steps of:
forming a supporting board having a first electrode formed on a first main surface of the supporting board, a second electrode formed on a second main surface of the supporting board, and an opening or notch forming part;
mounting a semiconductor element on the first main surface of the supporting board so that a second electrode pad of the semiconductor element faces the opening or notch forming part;
connecting a first electrode pad of the semiconductor element to the first electrode; and
electrically connecting the second electrode pad of the semiconductor element to the second electrode of the supporting board via the opening or notch forming part.

13. The manufacturing method of the semiconductor device as claimed in claim 12,
wherein the opening or notch forming part is formed in the vicinity of an edge part of a side of the supporting board or the vicinity of a corner part, in the step of forming the supporting board.

14. The manufacturing method of the semiconductor device as claimed in claim 12, further comprising the step of:
sealing the semiconductor element and the opening or notch forming part with resin after the step of connecting the second electrode pad to the second electrode.
